(19) United States
(12) Patent Application Publication
(10) Pub. No.: US 2025/0072145 A1
(43) Pub. Date: Feb. 27, 2025

(54) OPTICAL SENSING SYSTEM AND LIGHT GATING LAYER

(71) Applicant: PixArt Imaging Inc., Hsin-Chu City (TW)

(72) Inventor: Chia-Yu Liu, Hsin-Chu City (TW)

(73) Assignee: PixArt Imaging Inc., Hsin-Chu City (TW)

(21) Appl. No.: 18/237,891

(22) Filed: Aug. 24, 2023

(51) Int. Cl. H01L 27/146

(52) U.S. Cl. CPC H01L 27/14625; H01L 27/1461

(57) ABSTRACT

An optical sensing system comprising a first optical sensor. The first optical sensor comprises: a first pixel array; and a first light gating layer, configured to receive first input light and to provide first receiving light to the first pixel array, to make the first optical sensor has at least two different light sensitivities. The

### BACKGROUND OF THE INVENTION

### 1. Field of the Invention

The present invention relates to an optical sensing system and a light gating layer thereof, and particularly relates to an optical sensing system comprising an optical sensor with at least one light sensitivity which can be adjusted by a light gating layer, and relates to a light gating layer of the optical sensing system.

### 2. Description of the Prior Art

A conventional optical sensor can be used to sense optical data which is used for tracking or detecting an object. The sensing signals generated by the optical sensor may saturate if the optical sensor is close to a light source or receives strong light. However, the optical sensor always has only one fixed light sensitivity, thus it is hard to improve such issue.

### SUMMARY OF THE INVENTION

One objective of the present invention is to provide an optical sensor which may have at least two different light sensitivities.

Another objective of the present invention is to provide an optical sensor which may have at least two different light sensitivities via multi polarizer layers.

Another objective of the present invention is to provide a light gating layer with multi polarizer layers.

One embodiment of the present invention discloses an optical sensing system with a first optical sensor. The first optical sensor comprises: a first pixel array; and a first light gating layer, configured to receive first input light and to provide first receiving light to the first pixel array, to make the first optical sensor has at least two different light sensitivities.

Another embodiment of the present invention discloses an optical sensing system with a first optical sensor which comprises a first pixel array and a first light gating layer. The first light gating layer is configured to provide first receiving light to the first pixel array, comprising: a first polarizer layer, comprising a plurality of first polarizer strips, wherein each of the first polarizer strips has a first width, a first length, and a distance between different ones of the first polarizer strips is a first distance; and a second polarizer layer, comprising a plurality of second polarizer strips, wherein each of the second polarizer strips has a second width, a second length, and a distance between different ones of the second polarizer strips is a second distance.

Still another embodiment of the present invention discloses a light gating layer, comprising: a first polarizer layer, comprising a plurality of first polarizer strips, wherein each of the first polarizer strips has a first width and a first length, and a distance between different ones of the first polarizer strips is a first distance; and a second polarizer layer, comprising a plurality of second polarizer strips, wherein each of the second polarizer strips has a second width and a second length, and a distance between different ones of the second polarizer strips is a second distance. In view of above-embodiments, the light sensitivity of a sensor region or an optical sensor may be set via the structures of the light gating layer. Also, an optical sensor may have different light sensitivities. Accordingly, the light sensitivity of the sensor region or the optical sensor may be set corresponding to different requirements.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a first optical sensor according to one embodiment of the present invention.

FIG. 2 is a schematic diagram illustrating detail structures of the first polarizer layer and the second polarizer layer in FIG. 1, according to one embodiment of the present invention.

FIG. 3 is an exploded view of FIG. 2.

FIG. 4 is a schematic diagram illustrating the optical sensors with different exposing areas according to one embodiment of the present invention.

FIG. 5 is a schematic diagram illustrating an optical sensor with different light sensitivities, according to one embodiment of the present invention.

FIG. 6, FIG. 7 and FIG. 8 are schematic diagrams illustrating the light sensitivity distributions of different sensor regions, according to different embodiments of the present invention.

FIG. 9 is a schematic diagram illustrating an image sensing system comprising a plurality of image sensors, according to one embodiment of the present invention.

### DETAILED DESCRIPTION

Several embodiments are provided in following descriptions to explain the concept of the present invention. In following embodiments, the term “first”, “second”, “third” in following descriptions are only for the purpose of distinguishing different one elements, and do not mean the sequence of the elements. For example, a first device and a second device only mean these devices can have the same structure but are different devices.

In following embodiment, a term “light sensitivity” is used, which represents the intensity of the optical sensor's response to light. For example, if an optical sensor with a high light sensitivity and an optical sensor with a low light sensitivity receive the same amount of light, the signal intensities (e.g., the number of charges generated by pixels) of light sensing signals generated by the optical sensor with a high light sensitivity are larger than the signal intensities of light sensing signals generated by the optical sensor with a low light sensitivity. Further, the optical sensor in each embodiment may be an image sensor.

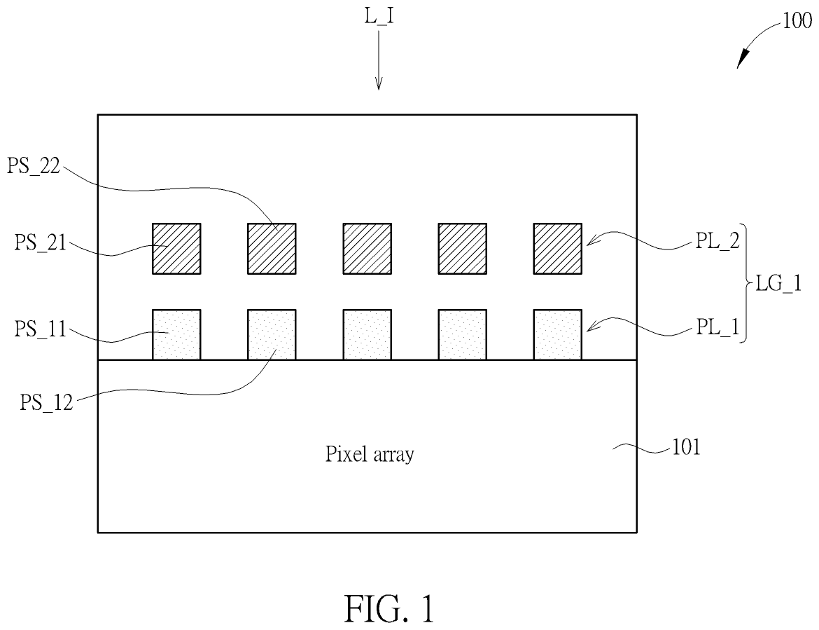

FIG. 1 is a schematic diagram illustrating a first optical sensor 100 according to one embodiment of the present invention. As illustrated in FIG. 1, the first image sensor 100 comprises a first pixel array 101 and a first light gating layer LG_1. The first light gating layer LG_1 is configured to receive first input light L_I and to provide first receiving light to the first pixel array 101, to control at least one light sensitivity of the first optical sensor 100. In other words, the first light gating layer LG_1 blocks at least portion of the first input light L_I to generate the first receiving light to the first pixel array 101. If the first light gating layer LG_1 blocks a large portion of the first input light L_I, the first optical sensor 100 has a low light sensitivity. On the contrary, if the first light gating layer LG_1 blocks a small portion of the first input light L_I, the first optical sensor 100 has a high light sensitivity.

In the embodiment of FIG. 1, the first light gating layer LG_1 comprises a first polarizer layer PL_1 and a second polarizer layer PL_2. The light sensitivity corresponds to the structure of the first polarizer layer PL_1 and the second polarizer layer PL_2. Please note, the first light gating layer LG_1 may comprise only one polarizer layer or more than two polarizer layers, rather than two polarizer layers illustrated in FIG. 1. Besides, in the embodiment of FIG. 1, the first light gating layer LG_1 is provided above the first pixel array 101, since a light receiving surface of the first pixel array 101 is a top surface thereof. However, the location of the first light gating layer LG_1 may be changed corresponding to the light receiving surface. For example, if the light receiving surface of the first pixel array 101 is a right surface thereof, the first light gating layer LG_1 is provided right to the first pixel array 101.

In the embodiment of FIG. 1, the first polarizer layer PL_1 comprises a plurality of first polarizer strips (only two first polarizer strips PS_11, PS_12 are illustrated for example), and the second polarizer layer PL_2 comprises a plurality of second polarizer strips (only two second polarizer strips PS_21, PS_22 are illustrated for example). In one embodiment, the first polarizer strips PS_11, PS_12 and the second polarizer strips PS_21, PS_22 are metal strips and are provided in a layer in which the signal lines of the optical sensor 100 are also provided, but not limited.

In one embodiment, the first image sensor 100 further comprises a micro lens located above the first light gating layer LG_1. The micro lens can also block partial of the input light L_I, thus can also be applied to control the light sensitivity of the optical sensor 100. However, the micro lens is optional and can be removed from the optical sensor 100.

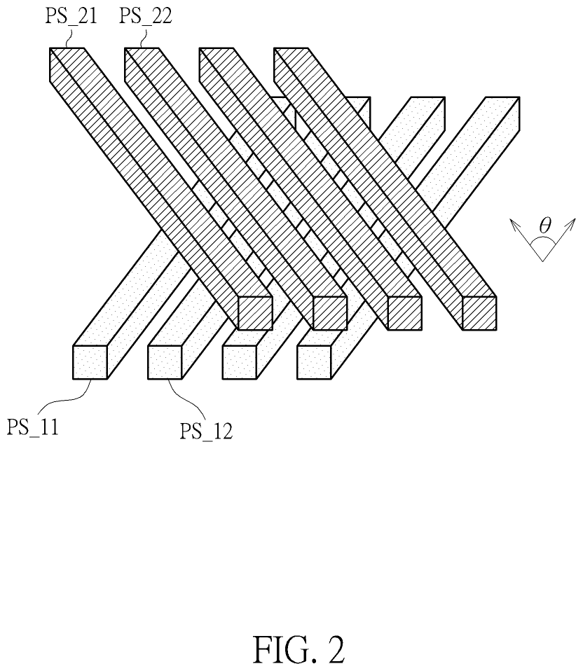

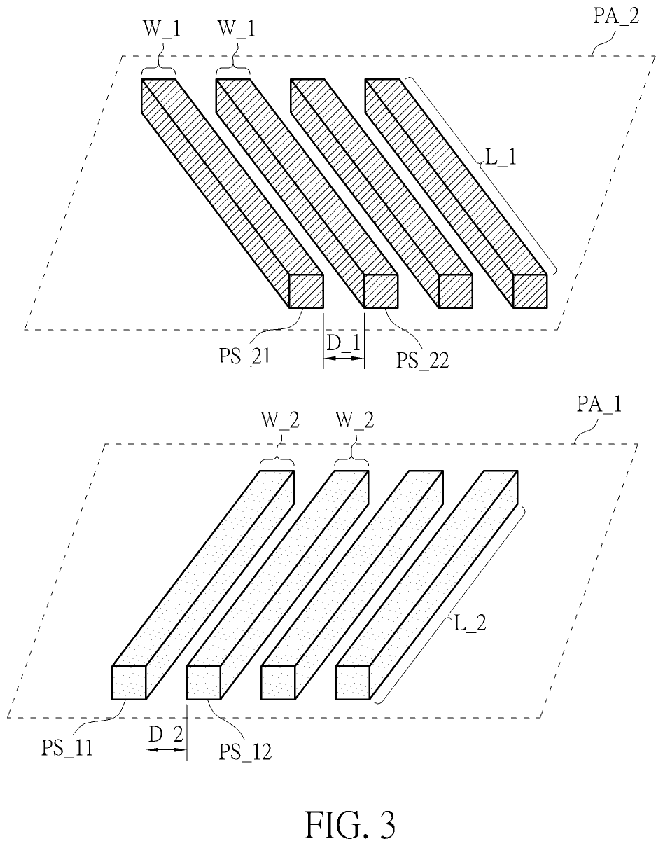

Detail structures of the first polarizer layer PL_1 and the second polarizer layer PL_2 are described in following embodiments. However, the first polarizer layer PL_1 and the second polarizer layer PL_2 are not limited to be implemented to an optical sensor. FIG. 2 is a schematic diagram illustrating detail structures of the first polarizer layer P 1 and the second polarizer layer P 2 in FIG. 1, according to one embodiment of the present invention. Also, FIG. 3 is an exploded view of FIG. 2.

As shown in FIG. 2, the second polarizer strips PS_21, 22 are directly provided on the first polarizer strips PS_11, PS_12. However, in another embodiment, another layer, other layers or other material can be provided between the first polarizer strips PS_11, PS_12 and the second polarizer strips PS_21, 22. Also, as shown in FIG. 3, each of the first polarizer strips PS_11, PS_12 has a first width W_1 and a first length L_1, and a distance between the first polarizer strips PS_11, PS_12 is a first distance D_1. Besides, as shown in FIG. 3, each of the second polarizer strips PS_21, PS_22 has a second width W_2 and a second length L_2, and a distance between the second polarizer strips PS_21, PS_22 is a second distance D_2. In one embodiment, the first width W_1 and the second width W_2 may be 1/N of a light wave length (e.g., ¼). Further, the first distance D_1 and the second distance D_2 may be identical with the first width W_1 and the second width W_2.

In one embodiment, the light sensitivity of the optical sensor 100 correspond to the first width W_1, the first length L_1, the first distance D_1, the second width W_2, the second length L_2 and the second distance D_2. In other words, the light transmittance of the first light gating layer LG_1 corresponds to the first width W_1, the first length L_1, the first distance D_1, the second width W_2, the second length L_2 and the second distance D_2. In another embodiment, the light sensitivity of the optical sensor 100 corresponds to the first width W_1, the first length L_1, the first distance D_1, the second width W_2, the second length L_2, the second distance D_2 and further corresponds to an angle θ between the first polarizer strips PS_11, PS_12 and the second polarizer strips PS_21, PS_22.

More specifically, in one embodiment, the first polarizer strips PS_11, PS_12 are parallel with each other, and the second polarizer strips PS_21, PS_22 are parallel with each other. Also, the angle θ may be a smallest angle between long sides of the first polarizer strips PS_11, PS_12 and long sides of the second polarizer strips PS_21, PS_22. Further, as shown in FIG. 3, the first polarizer strips PS_11, PS_12 are provided in a first plane PA 1 and the second polarizer strips PS_21, PS_22 are provided in a second plane PA 2 parallel with the first plane PA 1. The light sensitivity of the optical sensor 100 corresponds to the angle θ between the first polarizer strips PS_11, PS_12 and projection of the second polarizer strips PS_21, PS_22, wherein the projection is projected to the first plane PA 1.

The above-mentioned rules of the light sensitivity may be represented as following Equation (1):

$$L S ∝ K \times {T}^{2} \times {cos}^{2} θ \qquad Equation ( 1 )$$

LS means the light sensitivity. K is a constant value which can be set according to design requirements or material of the polarizer strip. In one embodiment, K is 0.5. T is a light transmittance of the polarizer layer, which may correspond to the above-mention widths and lengths of the polarizer strips and distances between polarizer strips. According to Equation (1), if the angle θ is close to 0°, the light sensitivity LS is larger since cos θ is close to 1. On the opposite, if the angle θ is close to 90°, the light sensitivity LS is smaller since cos θ is close to 0. In one embodiment, the light sensitivity of the optical sensor 100 may corresponds to the angle θ but does not corresponds to the widths and lengths of the polarizer strips. For example, in one embodiment, T is fixed via setting the widths and lengths of the polarizer strips. In such case, the light sensitivity of the optical sensor 100 may corresponds to the angle θ but does not corresponds to the widths and lengths of the polarizer strips.

As above-mentioned, the first light gating layer LG_1 may comprise only one polarizer layer. For example, the first light gating layer LG_1 only comprises the first polarizer layer PL_1. In such embodiment, the light sensitivity may correspond to the first width W_1, the first length L_1 and the first distance D_1. Also, in such embodiment, the light sensitivity may be represented as following Equation (2):

$$LS ∝ K \times T \qquad Equation ( 2 )$$

LS means the light sensitivity. K is a constant value which can be set according to design requirements or material of the polarizer strip. T is a light transmittance of the polarizer layer which may correspond to the above-mention widths and lengths of the polarizer strips and distances between polarizer strips.

The structures illustrated in FIG. 2 and FIG. 3 can be used for other applications rather than provide different light sensitivities to at least one optical sensor.

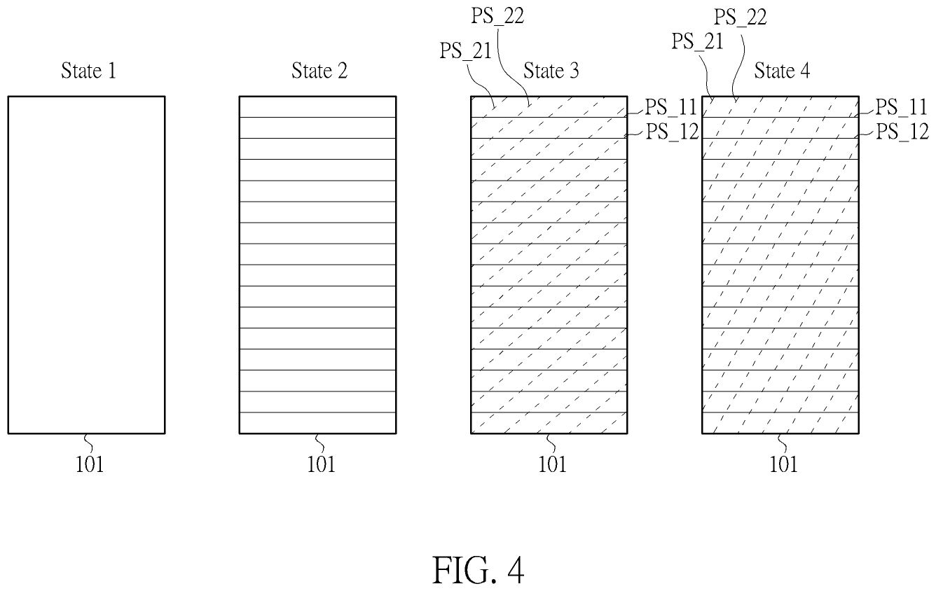

The above-mentioned θ may determine an exposing area of the first pixel array 101. The exposing area means a total area of the regions of the first pixel array 101 which are not blocked by any polarizer strip. FIG. 4 is a schematic diagram illustrating the first pixel array 101 with different exposing areas according to one embodiment of the present invention. In State 1, no polarizer strips are provided on the first pixel array 101, thus the first pixel array 101 is not blocked and has a maximum exposing area. In State 2, the first polarizer strips PS_11, PS_12 and the second polarizer strips PS_21, PS_22 almost totally overlaps (angle θ is 0° or close to) 0°, but a portion of the pixel array 101 is still blocked, thus the exposing area in State 2 is smaller than the exposing area in State 1.

The angle θ in State 3 is larger than the angle θ in State 2, thus only a portion of the second polarizer strips PS_21, PS_22 overlaps with the first polarizer strips PS_11, PS_12, such that the exposing area in State 3 is smaller than the exposing area in State 2. Also, the angle θ in State 4 is larger than the angle θ in State 3. However, since the widths, the lengths and the numbers of the second polarizer strips PS_21, PS_22 in State 4 are almost the same as the widths, the lengths and the numbers of the second polarizer strips PS_21, PS_22 in State 3. Accordingly, the exposing area in State 3 and the exposing area in State 4 are identical or only have a small difference. However, the light sensitivities of the optical sensor 100 are different in the State 3 and State 4, according to the above-mentioned Equation (1). Accordingly, in view of the embodiment illustrate in FIG. 4, the optical sensor may have different light sensitivities even if the exposing areas of pixel arrays thereof are the same or very close.

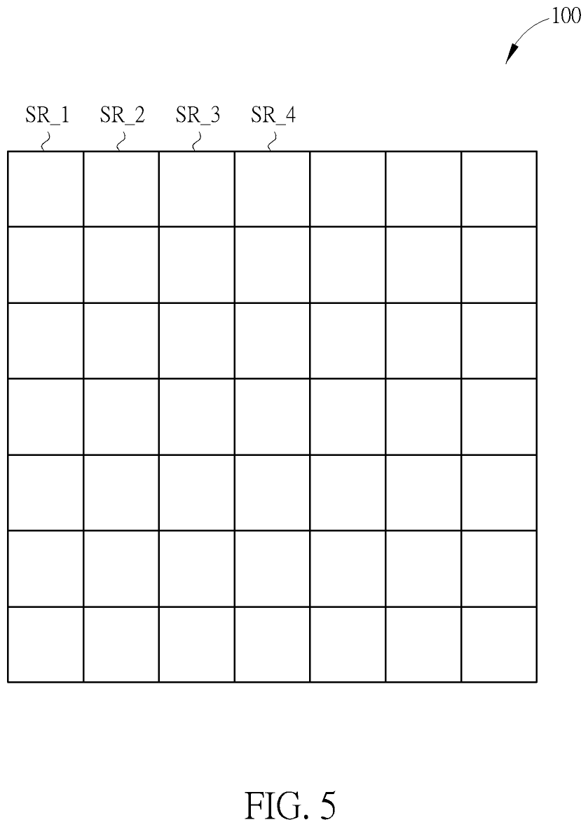

In above-mentioned embodiments, an optical sensor has only one light sensitivity. However, in the present invention, an optical sensor may have more than one different light sensitivity. FIG. 5 is a schematic diagram illustrating an optical sensor with different light sensitivities, according to one embodiment of the present invention. As illustrated in FIG. 5, the first optical sensor 100 comprises a plurality of sensor regions (only four sensor regions SR_1, SR_2, SR_3 and SR_4 are symbolized for explaining in FIG. 5). The sensor regions SR_1, SR_2, SR_3 and SR_4 are located at different locations of the first optical sensor 100. Each of the sensor regions SR_1, SR_2, SR_3 and SR_4 comprises at least one pixel. The sensor regions SR_1, SR_2, SR_3 and SR_4 may have an identical light sensitivity or different sensitivities. For example, the sensor regions SR_1, SR_2, SR_3 and SR_4 may all have a first light sensitivity. For another example, the sensor regions SR_1, SR_2 have a first light sensitivity, and the sensor regions SR_3, SR_4 have a second light sensitivity.

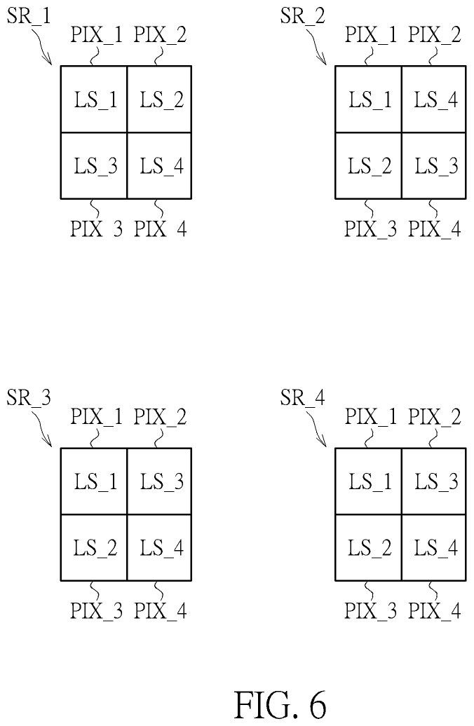

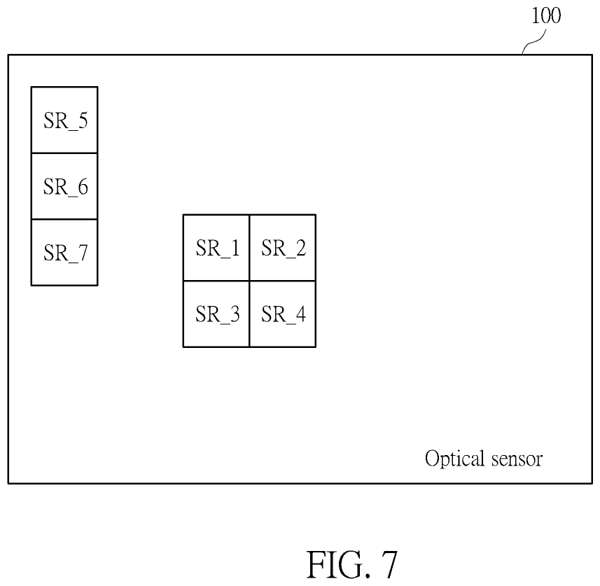

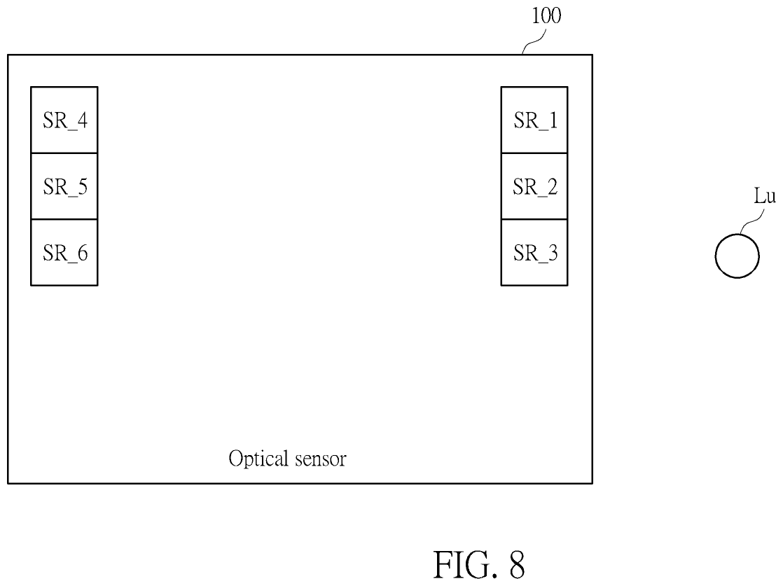

FIG. 6, FIG. 7 and FIG. 8 are schematic diagrams illustrating the light sensitivity distributions of different sensor regions, according to different embodiments of the present invention. In one embodiment, the light sensitivities of the pixels in each one of the sensor regions distribute following different rules. As shown in FIG. 6, the sensor regions SR_1, SR_2 both comprises pixels PIX_1, PIX_2, PIX_3 and PIX_4. For the sensor region SR_1, the pixels PIX_1, PIX_2, PIX_3 and PIX_4 respectively comprises light sensitivities LS_1, LS_2, LS_3 and LS_4. However, for the sensor region SR_2, the pixels PIX_1, PIX_2, PIX_3 and PIX_4 respectively comprises light sensitivities LS_1, LS_4, LS_2 and LS_3. Accordingly, the light sensitivities of the pixels in each one of the sensor regions SR_1, SR_2 distribute following different rules.

In another embodiment, each of the sensor regions has at least two different light sensitivities, and the light sensitivities of each one of the sensor regions distribute following identical rules. As shown in FIG. 6, the sensor regions SR_3, SR_4 both comprises pixels PIX_1, PIX_2, PIX_3 and PIX_4. For the sensor region SR_3, the pixels PIX_1, PIX_2, PIX_3 and PIX_4 respectively comprises light sensitivities LS_1, LS_3, LS_2 and LS_4. Besides, for the sensor region SR_4, the pixels PIX_1, PIX_2, PIX_3 and PIX_4 respectively comprises light sensitivities LS_1, LS_3, LS_2 and LS_4. Accordingly, the light sensitivities of the pixels in each one of the sensor regions SR_3, SR_4 distribute following identical rules.

In one embodiment, each of the sensor regions comprises at least one R pixel, at least one G pixel and at least one B pixel. The R pixel, the G pixel and the B pixel have different light sensitivities. Take the sensor region SR_1 in FIG. 6 for example, pixels PIX_1, PIX_2, PIX_3 and PIX_4 are respectively a R pixel, a G-pixel, a G-pixel and a B pixel. However, in such case, the pixels PIX_1, PIX_2, PIX_3 and PIX_4 of the sensor region SR_1 respectively comprises light sensitivities LS_1, LS_2, LS_2 and LS_4 since the pixels PIX_2, PIX_3 are G pixels, rather than light sensitivities LS_1, LS_2, LS_3 and LS_4 shown in FIG. 6.

In one embodiment, the light sensitivities of the sensor regions correspond to locations of the sensor regions. As shown in FIG. 7, the sensor regions SR_1, SR_2, SR_3 and SR_4 are located at a center of the first optical sensor 100, and the sensor regions SR_5, SR_6, SR_7 are located at a left up portion of the first optical sensor 100. In such embodiment, the sensor regions SR_1, SR_2, SR_3 and SR_4 comprise a first light intensity or a first light intensity distribution, and the sensor regions SR_5, SR_6, SR_7 comprise a second light intensity or a second light intensity distribution.

In one embodiment, the optical sensing system further comprises a light source, and the light sensitivities of the sensor regions are inversely related with distance between the sensor regions and the light source. As shown in FIG. 8, the optical sensing system further comprises a light source Lu. In such embodiment, the sensor regions SR_1, SR_2 and SR_3 have at least one smaller light sensitivity since they are closer to the light source Lu. Oppositely, the sensor regions SR_4, SR_5 and SR_6 have at least one larger light sensitivity due to their greater distance from the light source Lu.

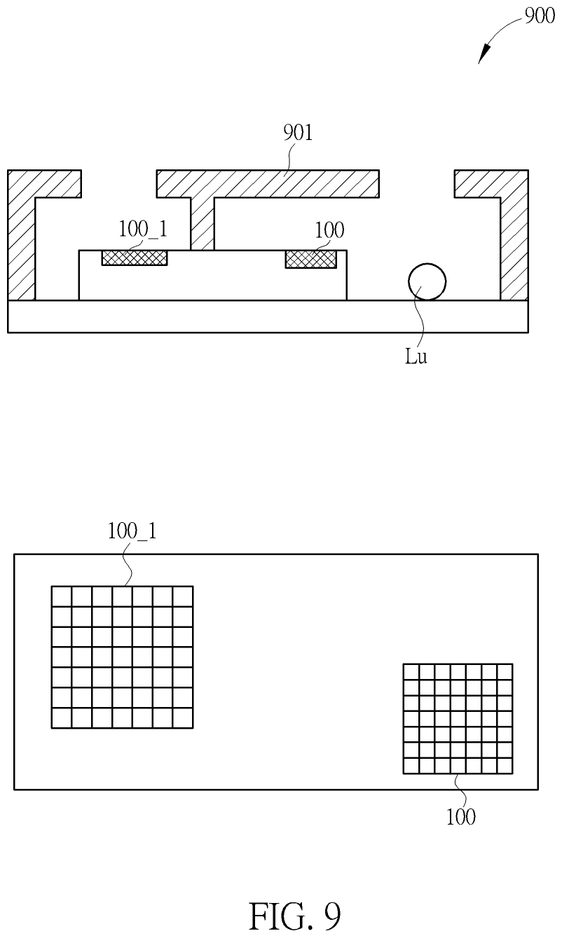

In above-mentioned embodiments, the optical sensing system comprises only one optical sensor (i.e., the first optical sensor 100). However, the optical sensing system provided by the present invention may comprise more than one optical sensor. FIG. 9 is a schematic diagram illustrating an image sensing system 900 comprising a plurality of image sensors, according to one embodiment of the present invention. As shown in the upper diagram of FIG. 9, the image sensing system 900 comprises the above-mentioned first optical sensor 100 and a second optical sensor 100_1. The lower diagram of FIG. 9 is a top view of the upper diagram of the first optical sensor 100 and the second optical sensor 100_1.

In FIG. 9, the image sensing system 900 further comprises a light source Lu and a housing 901. The housing 901 may block the light from the light source Lu. Accordingly, the first optical sensor 100 receives the light from the light source Lu or reflected light of the light, but the second optical sensor 100_1 does not receive the light and the reflected light. In such example, the embodiment shown in FIG. 8 may be implemented to the first optical sensor 100.

In one embodiment, mage sensing system 900 is applied to a TOF (Time of Flight) system. In such case, the second optical sensor 100_1 may second optical data generated according to ambient light or according to reflected light of the light from the light source Lu or another light source, to detect proximity of an object. Also, the optical data sensed by the first optical sensor 100 is configured to compute the interference caused by ambient light. By this way, the detection of the object can be more accurate. Therefore, in one embodiment, the at least one light sensitivity of the second optical sensor 100_1 may be determined by the scenarios of the TOF system. For example, if the TOF system may be provided in a place which always has strong light, the light sensitivity can be set to be low. On the contrary, if the TOF system may be provided in a place which is always dark, the light sensitivity can be set to be high.

The second optical sensor 100_1 may have the structure in above-mentioned embodiments. Specifically, the second optical sensor 100_1 comprises a second pixel array and a second light gating layer. The second light gating layer is configured to receive second input light and to provide second receiving light to the second pixel array, to make the second optical sensor has at least two different light sensitivities. In one embodiment, the second light gating layer comprises a third polarizer layer and a fourth polarizer layer. The third polarizer layer and the fourth polarizer layer may have structures the same as the structures of the above-mentioned third polarizer layer and the fourth polarizer layer. More specifically, the third polarizer layer comprises a plurality of third polarizer strips, wherein each of the third polarizer strips has a third width, a third length, and a distance between different ones of the third polarizer strips is a third distance. The fourth polarizer layer comprises a plurality of fourth polarizer strips, wherein each of the fourth polarizer strips has a fourth width, a fourth length and a distance between different ones of the fourth polarizer strips is a fourth distance.

Other details of the second optical sensor may be acquired in view of above-mentioned embodiments, thus are omitted for brevity here.

In view of above-embodiments, the light sensitivity of a sensor region or an optical sensor may be set via the structures of the light gating layer. Also, an optical sensor may have different light sensitivities. Accordingly, the light sensitivity of the sensor region or the optical sensor may be set corresponding to different requirements.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An optical sensing system, comprising:
a first optical sensor, comprising:
a first pixel array; and
a first light gating layer, configured to receive first input light and to provide first receiving light to the first pixel array, to make the first optical sensor has at least two different light sensitivities.

2. The optical sensing system of claim 1, wherein the first light gating layer comprises:
a first polarizer layer, comprising a plurality of first polarizer strips, wherein each of the first polarizer strips has a first width and a first length, and a distance between different ones of the first polarizer strips is a first distance;
wherein the light sensitivities correspond to the first width, the first length and the first distance.

3. The optical sensing system of claim 1, wherein the first light gating layer comprises:
a first polarizer layer, comprising a plurality of first polarizer strips, wherein each of the first polarizer strips has a first width and a first length, and a distance between different ones of the first polarizer strips is a first distance; and
a second polarizer layer, comprising a plurality of second polarizer strips, wherein each of the second polarizer strips has a second width and a second length, and a distance between different ones of the second polarizer strips is a second distance.

4. The optical sensing system of claim 3, wherein the light sensitivities correspond to the first width, the first length, the first distance, the second width, the second length and the second distance.

5. The optical sensing system of claim 3, wherein the first polarizer strips are provided in a first plane and the second polarizer strips are provided in a second plane parallel with the first plane, wherein the light sensitivities correspond to an angle between the first polarizer strips and projection of the second polarizer strips, wherein the projection is projected to the first plane.

6. The optical sensing system of claim 1, wherein the first optical sensor comprises a plurality of sensor regions respectively comprising a plurality of pixels, wherein each of the sensor regions has at least two different ones of the light sensitivities, and the light sensitivities of each one of the sensor regions distribute following identical rules.

7. The optical sensing system of claim 6, wherein each of the sensor regions comprises at least one R pixel, at least one G pixel and at least one B pixel, wherein the R pixel, the G pixel and the B pixel have different ones of the light sensitivities.

8. The optical sensing system of claim 1, wherein the first optical sensor comprises a plurality of sensor regions, wherein the sensor regions are located at different locations of the first optical sensor and comprises a plurality of pixels, wherein the light sensitivities of the pixels in each one of the sensor regions distribute following different rules.

9. The optical sensing system of claim 1, further comprising:
a second optical sensor, comprising:
a second pixel array; and
a second light gating layer, configured to receive second input light and to provide second receiving light to the second pixel array, to make the second optical sensor has at least two different light sensitivities.

10. The optical sensing system of claim 9, further comprising:
a light source, configured to emit light;
wherein the first optical sensor receives the light or reflected light of the light;
wherein the second optical sensor does not receive the light and the reflected light.

11. The optical sensing system of claim 1, comprising:
a light source;
wherein the first optical sensor comprises a plurality of sensor regions;
wherein the light sensitivities of the sensor regions are inversely related with distance between the sensor regions and the light source.

12. An optical sensing system, comprising:
a first optical sensor, comprising:
a first pixel array; and
a first light gating layer, configured to provide first receiving light to the first pixel array, comprising:
a first polarizer layer, comprising a plurality of first polarizer strips, wherein each of the first polarizer strips has a first width, a first length, and a distance between different ones of the first polarizer strips is a first distance; and
a second polarizer layer, comprising a plurality of second polarizer strips, wherein each of the second polarizer strips has a second width, a second length, and a distance between different ones of the second polarizer strips is a second distance.

13. The optical sensing system of claim 12, wherein light sensitivities of the first optical sensor correspond to the first width, the first length, the first distance, the second width, the second length and the second distance.

14. The optical sensing system of claim 12, wherein the first polarizer strips are provided in a first plane and the second polarizer strips are provided in a second plane parallel with the first plane, wherein the light sensitivities correspond to an angle between the first polarizer strips and projection of the second polarizer strips, wherein the projection is projected to the first plane.

15. The optical sensing system of claim 12, further comprising:
a second optical sensor, comprising:
a second pixel array; and
a second light gating layer, comprising:
a third polarizer layer, comprising a plurality of third polarizer strips, wherein each of the third polarizer strips has a third width, a third length, and a distance between different ones of the third polarizer strips is a third distance; and
a fourth polarizer layer, comprising a plurality of fourth polarizer strips, wherein each of the fourth polarizer strips has a fourth width, a fourth length and a distance between different ones of the fourth polarizer strips is a fourth distance.

16. The optical sensing system of claim 15, further comprising:
a light source, configured to emit light;
wherein the first optical sensor receives the light or reflected light of the light;
wherein the second optical sensor does not receive the light and the reflected light.

17. A light gating layer, comprising
a first polarizer layer, comprising a plurality of first polarizer strips, wherein each of the first polarizer strips has a first width and a first length, and a distance between different ones of the first polarizer strips is a first distance; and
a second polarizer layer, comprising a plurality of second polarizer strips, wherein each of the second polarizer strips has a second width and a second length, and a distance between different ones of the second polarizer strips is a second distance.

18. The light gating layer of claim 17, wherein a light transmittance of the light gating layer correspond to the first width, the first length, the first distance, the second width, the second length, and the second distance.

19. The light gating layer of claim 17, wherein the first polarizer strips are provided in a first plane and the second polarizer strips are provided in a second plane parallel with the first plane, wherein the light sensitivities correspond to an angle between the first polarizer strips and projection of the second polarizer strips, wherein the projection is projected to the first plane.
